(19) United States
(12) Patent Application Publication
(10) Pub. No.: US 2025/0164938 A1
(43) Pub. Date: May 22, 2025

(54) ERGODIC TIME TO DIGITAL CONVERTER

(71) Applicant: CODRUT Radu RADULESCU, West Orange, NJ (US)

(72) Inventor: CODRUT Radu RADULESCU, West Orange, NJ (US)

(21) Appl. No.: 18/840,465

(22) PCT Filed: Feb. 22, 2023
(86) PCT No.: PCT/US2023/063085

§ 371 Date: Aug. 21, 2024

(51) Int. Cl. G04F 10/00; H03M 1/10

(52) U.S. Cl. CPC G04F 10/005; H03M 1/1028

(57) ABSTRACT

A time to digital converter (TDC) comprising a tapped delay line (TDL) having two or more sectors, each sector of the two or more sectors having a dedicated or a shared latching clock, or two or more TDLs each having at least one sector, wherein each TDL of the two or more TDLs includes a dedicated latching clock for each sector, and a snapshot register (TDLSecS) configured to latch the sector on its respective latching clock to generate a thermometer reading.

### 1. BACKGROUND

Time to Digital Converters (TDCs) provide a numerical timestamp for transitions of a digital signal, relative to a reference clock. An implementation of a TDC uses tap delay lines (TDL) to provide timestamps with granularity smaller than the period of one clock. Multiple TDLs can be used to further improve precision.

Ergodicity assumes the same probability for the results of an experiment performed in parallel on multiple instances and performed in time on multiple repetitions. The propose system may capture an event on all or on a subset of entities, depending on the space and time relation between the signal path structure, the event, and the latching clocks. Any timestamps produced by a subset of capturing entities are representative as if taken with the full set of entities. Each capture has equivalent precision characteristics regardless of entity location or latching clocks. An Ergodic TDC is an extended traditional TDC which performs an average of measurements of the same event by multiple TDCs, using a plurality of clocks.

### 2. SUMMARY

Aspects of the disclosure are directed to high precision time to digital converters. One aspect of the disclosure is directed to a time to digital converter (TDC) comprising a tapped delay line (TDL) having two or more sectors, each sector of the two or more sectors having a dedicated or a shared latching clock, or two or more TDLs each having at least one sector, wherein each TDL of the two or more TDLs includes a dedicated latching clock for each sector; and a snapshot register configured to latch each respective sector on its respective latching clock to generate respective thermometer readings (TDLSecSs).

In some instances, the TDC may comprise at least one encoder configured to generate a numerical representation (TDLSecSE) of each of the thermometer readings, wherein each TDLSecSE is generated by encoding a location of a transition in a TDLSecS or between adjacent TDLSecSs.

In some examples, the TDC includes one or more adders, wherein the one or more adders are configured to generate a timestamp (TDLSecTS) for each respective TDLSecSE by adding a delay (PhOff) to each respective TDLSecSE, wherein the delay is relative to a common reference.

In some examples, TDC further includes a processor, wherein the processor is configured to determine a sum or an average of TDLSecTSs generated by an event signal.

Encoding may comprise: calculating a sum of all bits of the TDLSecSs; and if the sum is different from a compact sum which is either null or equal with a total number of bits of TDLSecS, and the sum of a first plurality of bits near the signal entry to the TDLSecS is bigger than the sum of a second plurality of bits at the opposite end of the TDLSecS, then TDLSecSE referenced from the end point of signal entry to TDLSecS is valid and is equal with the sum, and the transition is a rising edge, or the sum of a first plurality of bits near the end point of signal entry to the TDLSecS is smaller than the sum of a second plurality of bits at the opposite end of the TDLSecS then TDLSecSE, referenced from the signal entry end point of TDLSecS is valid and is equal with the difference between the number of bits in the TDLSecS and the sum, and the transition is a falling edge; or if the sum of TDLSecS is compact and not null and the sum of an adjacent TDLSecS connected at the output of the TDLSecS is compact and null then the TDLSecSE referenced from the end point of signal entry of TDLSecS is the total number of bits of TDLSecS, and the transition is valid and is positive, if the sum of TDLSecS is compact and null and the sum of an adjacent TDLSecS connected at the output of the TDLSecS is compact and not null then the TDLSecSE referenced from the end point of signal entry of TDLSecS is the total number of bits of TDLSecS and the transition is negative, or if the sum of TDLSecS is compact and the sum of an adjacent TDLSecS connected at the output of the TDLSecS is also compact and both sums are equal TDLSecSE is not valid.

In some examples, a maximum number of timestamps generated by the TDC at an output is up to a maximum number of sectors on TDLs with different clocks and the maximum number of sectors on TDLs with different clocks is further divided by a number of latching clock periods in between each generated timestamp from each TDLSecS.

In some examples, a minimum time interval between two timestamps is equal or greater than a TDLSec time interval.

In some examples, TDC further comprises a first snapshot subsystem comprising: a first TDL connected to an event signal and latched into a first snapshot register by a first clock, a second clock with a known, deterministic relation to the first clock, and the second TDL connected to the event signal and latched into a second snapshot register by the second clock; and a second snapshot subsystem comprising: a third TDL connected to the event signal and latched into a third snapshot register by the first clock, and a fourth TDL connected to the event signal and latched into a fourth snapshot register by the second clock; and a logic block generating timestamps from data collected in the four snapshot registers from both snapshot subsystems. The logic block may further comprise: a processing unit configured to perform either: an average of a tap delay of a signal transition in a time overlapping section at one end of the first snapshot register with a tap delay of a signal transition in the time overlapping section at the other end of the second snapshot register, or a selection among the tap delay of a signal transition signal in the time overlapping section at one end of the first snapshot register and the tap delay of a signal transition signal in the time overlapping section at the other end of the second snapshot register.

In some examples, the TDC includes the two or more TDLs including a first TDL and a second TDL, wherein a signal transition is captured on the first TDL, on the second TDL, or an overlapping section of the first and second TDL. In some examples, each TDL has a propagation delay shorter than a period of its respective latching clock. In some examples, any signal transition is captured by a plurality of the TDLs.

In some examples, the TDC is configured to: measure FPGA hardware and select TDL taps and associated routing to latching registers for a preselected FPGA CARRY chain, or select, from a plurality of FPGA CARRY chains, a subset of the plurality of FPGA CARRY chains having TDL taps distributions, wherein the delay between consecutive TDL taps of the subset of FPGA CARRY chains or preselected FPGA CARRY chain is similar or equal.

In some instances, the TDC further comprises a raw counter of a first latching clock or a raw counter of a second latching clock or both or an additional software counter for either or both the raw counters wherein the raw counter wraps around and provides and provides a dynamic range equal with a maximum count number. In some instances, a shortest detectable signal pulse is a propagation time of a signal through a TDLSec. In some instances, the TDC is configured to measure a respective delay of each TDL tap through a calibration process.

In some examples, the TDC is further configured to convert a TDL tap number of a transition into a propagation delay from an input of a sector to the TDL tap.

In some examples, the TDC is further configured to measure a relative propagation delay offset (PhOff) between a common signal reference point and the first TDL tap of each TDL.

In some examples, the TDC is configured to disambiguate a signal transition, wherein disambiguating the same signal event in a time overlapping section of two adjacent TDLSec, includes: determining the start and ending tap number or time of the overlapping section of two time adjacent TDLSec by identifying a range where same polarity transition is detected on both TDLSecs, converting the transition (TDLSecSE) from one of the TDLSec to the other TDLSec by adding a time constant or subtracting another time constant, and adding or averaging the two TDLSecSE at the same TDLSec. In some instances, the time constant is added to the earlier timestamp captured by the first TDLSecS for conversion to the second TDLSecS, or the time constant subtracted from the later timestamp captured by the second TDLSecS for conversion to the first TDLSecS is a difference of the PhOff of the first TDLSecS and the PhOff of the second TDLSecS.

In some examples, the TDC is further configured to retime the TDLSecS or TDLSecSE captured by one of the TDL with a second clock, to become contemporaneous to a time domain of a first clock. In some examples, converting the timing of transition events captured at a TDLSec to a timestamp relative to the signal input pin of the device includes: determining a PhOffSec time delay between the device pin and the first tap of the TDLSec input; determining a phase offset, PhOffSCK between the latching clock of TDLSecS and the reference clock incrementing the SCKCTR; and adding the PhOffSCK, and the PhOffSecto the TDLSecSE of the sector.

In some instances, the TDC is further configured to perform a calibration and measure of a sector through a sweeping wave comprising by: selecting a Phase Progression constant, representing the precision of the measurement, and generating a signal with a period determined by the period of the first clock modified by the Phase Progression; or generating a signal with a period close to the first clock, and determining the Phase Progression by counting a first number of periods of the first clock between transitions of same polarity of the same tap of the sector, and dividing the period of the first clock by the first number of periods; and determining the delay of a tap by counting a second number of periods of the first clock between a transition of the first tap of and a transition of the second tap, and multiplying the second number of periods with the phase progression. In some examples, the calibration is performed separately for the positive edge or for the negative edge of the event signal, or for both.

In some instances, the TDC further comprises a LUT to linearize, or convert tap numbers to a time delay of the tap number for the positive edge or for the negative edge of the event signal, or for both.

In some examples, the TDC is further configured to implement pseudo differential logic to mitigate noise, wherein the logic inverts the signal polarity for half of the TDL inputs of an ETDC and restores the original polarity by inverting the TDLSecS.

### 3. DESCRIPTION OF THE FIGURES

FIG. 1 is a block diagram illustrating the configuration of a TDC

FIG. 2 is a block diagram illustrating an ETDC architecture.

FIG. 3 is a graph illustrating the relationship between the clock and TDL coverage.

FIG. 4 illustrates an overlapping TDL window of a TDL represented on a continuous time axis.

FIG. 5 illustrates a different relative signal event delay to SCK for the parallel TDLs.

FIG. 6 illustrates a TDL and TDLSec content relation to the latching clock and PhOff.

FIG. 7 illustrates one clock with several signal delays (Phase Offset).

FIG. 8 is an illustration of the structure of a TDL.

FIG. 9 is a graph illustrated a tap delay as indexed by manufacturer and sorted by delay.

FIG. 10 is a block diagram of a calibration FPGA.

FIG. 11 illustrates an example of determining the TS for TDL.

FIG. 12 shows a conversion of Tap # to delay linearizes the overlapping and mending of TDLs latched by distinct phased SCK.

FIG. 13 illustrates overlapping TDCs with different clocks.

FIG. 14 is a block diagram of a compactor.

FIG. 15 illustrates the effect of latching a set of TDC on a second, phase delayed clock is equivalent with a similar delayed input signal for a same latching clock.

FIG. 16 illustrates TDLs having similar delay to the event pin, but latched by different phased clocks.

FIG. 17 illustrates overlapping TDLs and TDLSec relative to the latching clocks and SCKCtr changes.

FIG. 18 Illustrates TDLs clocked with one phase SCK, with input delayed by random values, covering an entire clock period.

FIG. 19 Illustrates a incrementally delaying latching of several TDLs to scatter the capture window is equivalent to incrementally delaying the input signal routing delay and latching TDLs with the same clock.

FIG. 20 is a graph showing a measured delay of the tap number for a TDL.

FIG. 21 is a graph showing linearization by replacing tap number with a delay.

FIG. 22 is a graph showing a tap number in the order of corresponding measured delay on the TDL.

FIG. 23 is a graph showing slight deviation from a perfect linear characteristic when delay values are truncated to 8 MSbit representation by forcing the two LSb to 0 for a section of 41 taps, out of the total of 480, with a total delay, TDLD of ˜1000 ps.

FIG. 24 is a graph showing a TDCS measured continuous characteristic.

### 4. DETAILED DESCRIPTION

### Introduction

The delay line-based Time to digital converter (TDC) described herein is timestamping events, allowing measurement precision of a fraction of the clock period. It comprises a raw counter for the clock periods, a tapped delay line (TDL) (typically having an equal delay in between adjacent taps), and a digital encoder which converts the “thermometer read” snapshot of the TDL (TDLS) into a digital number. The signal to be measured is feeding the input of the delay line, and a known clock (Clk), snapshot clock (SCK) latches the status of the TDL's taps into a Flip-Flop (FF) registers (TR). The time event signal propagates between the beginning and end of a TDL. This propagation delay can be longer or shorter than the period of the Clk, depending on chip technology and application. The precision of delay of individual taps of the TDL is the precision of the TDC. The ambient conditions, voltage, temperature, the design, and the technology dispersion, induce parasitic variations of the actual tap delays.

A TDC has two functional groups, analog and digital. The analog group (120), where the signal propagating through a plurality (one or more) TDLs, and it is latched on the active edge of a clock (the “snapshot”, TDLS), into flip flop registers, as a “thermometer read value”, which is a sequence of strings of high (“1”) and strings of low (“0”) values (binary 0 or 1). The digital group (130) converts the thermometer read values (103) to a binary encoded number, which is further numerically processed to generate a timestamp, representing the time an event occurred at the input pin.

In general, the performance of a TDC is defined by the linearity, accuracy and precision of the Timestamps, the internal noise, the dead time post acquisition of a timestamp, and the sustained number of timestamps acquired per second.

The digital group (130) generates the numerical, binary encoded timestamp information comprising a raw clock counter, the transition time relative to the clock period bounds, and the status flags for each sector (for example: Valid transition, positive or negative edge nature of transition, double capture transitions on different TDLs, errors)

Timestamp precision depends on the internal noise impacting both the jitter of the clock, and the event signal to be timestamped, and also the quantization error equal with the longest delay tap. The transition between the all 1 and all 0 bit sequences can be noisy, appearing as a random sequence of 0 and 1 at the edge of a thermometer reading transition, sometimes referred as bubble error; Example: 111110100110100000. This is implicitly solved by a sum-based encoder method, which counts the occurrences of “1” or “0” in a TDLS. The sum indicates the tap location of the actual transition.

To optimize implementation, TDLs are divided into sectors, TDLSec and each TDLSec is further divided in slices TDLSecSla. The encoder associated with a sector receives the thermometer reading of that sector and determines the most probable tap number for the transition within the sector, Tap number is further converted (for instance through a lookup table, LUT) to a local time stamp, TDLSecTS indicating the time of the transition relative to the sector time bounds. A timestamp (TS) relative to reference point (for example the pin of the device) is computed by adding the TDLSecTS to an associated Phase Offset representing the propagation delay between the reference point and that TDL Sector, PhOffSec. Also a raw counter, SCKCtr counting the main latching clock is associated with the TS. The sum-based encoder implements an integration process, which filters out the noise and provides an accurate position of the transition. The numerical processing steps involving addition can be executed in any order, due to its properties of commutativity, associativity, or distributivity The ETDC has several TDLs instances capturing the event signal on several clocks active edge. A TDC comprises a horizontal TDL plurality which covers a full clock period. An ETDC comprises a vertical plurality of TDC. The TDLSec readings can be added horizontally to generated TS or vertically to generate sums of the taps delay for a transition across overlapping TDLSec, and then summed together to determine the most probable transition. The sequence of adding the plurality of taps or time delays is optimized to match the input and output characteristics of the underlying technology of the FPGA or ASIC. In some embodiments, a numeric base 4 (2 bits) or base 8 (3 bits) may be used to increase or maximize the use of LUT architecture of the Xilinx chips having 6 inputs. Three terms of 2 bits (base 4) or two terms of 3 bits (base 8) can fully utilize the LUT resources, which also improves the routing.

An embodiment of this technology combines parallel TDL and encoders with different, deterministic latching clocks. Additional performance improvement is achieved through several calibration steps, comprising hardware (HW) and software (SW) calibration.

A carry chain selection HW calibration process, performs hardware measurement and selection of internal TDL instance location on the chip. It measures TDL parameters from several regions of the FPGA, which differ due to technology dispersion of local features of the device. Selection of optimal subset of taps of the TDLs provides a better linear characteristic for increased precision.

The carry chains and taps with most uniform parameters, are selected and their location is converted by scripts into the FPGA place and route data. Scripts can be used to automatically measure, select, and provide to the placement tools the optimal location parameters on the chip for the TDLs. A minimal set of placement and time constraint allows the FPGA tools to optimize the design and provide and economic and performant implementation.

TS accuracy is further improved by a SW calibration process, determining the delay for each tap of each TDLSec, the overlapping taps between TDLs and the delay offset between the TDLs signal input, referenced to a common clock.

A TDL provides thermometer data readings. In some embodiments of the encoder continuously reads the TDLS (103) by latching the thermometer read pattern for each TDLSec, at every active edge of the clock. An encoder can be allocated to each TDLSec or an encoder can be shared among several TDLSec. The encoder identifies and measures any transition in a TDLSec or at the bounds between two adjacent TDLSec and provides the most probable tap of the transition and a valid flag. Invalid TDLSec (not having a TS of a transition) are removed from the data flow and replaced with the next TDLSec Valid TS at the compactor stage (140). ETDC will output only TS of identified transitions, with a maximum rate of clock frequency multiplied by the maximum number of TDLSec latched by one clock.

Some ETDC embodiments may convert the transition tap number of a TDLSec into a local tap delay, TDLSecTS. Another embodiment further shifts, or translates it in time, from the time domain of the latching clock to the time domain of the reference clock (SCK), such that they can be associated and processed within the same SCKCtr slot. Other embodiment translates in time a TDLSecTs by the PhOffSec, according to the relative phase offset of each sector.

### SW Calibration

The CARRY chain provides the smallest granularity of delay tap intervals for FPGA logic. But some of the taps have very short while others have longer delay relative to the neighboring tap. Random events can statistically fall in any of the tap intervals proportional only with the delay of each interval, therefore for repeating measurements, a statistical average will provide the effective accuracy combining all the taps. But the precision of an individual event measurement, and its maximum error is determined by the longest tap delay intervals of the TDL. The ETDC performs parallel measurements of the same event by a plurality of TDLSec. It is assumed that the multiple TSLSec measurements at one time provide similar precision as multiple sequential measurement on a single TDLSec. Moreover the parallel measurements result in overlapping of multiple sets of taps covering the same time interval. More taps for the same interval result in shorter delay intervals between consecutive taps, providing smaller granularity and better precision.

Some implementations avoid the use of regular fabric interconnections and switch boxes, which can add significant jitter to signals. The TDLs signals are connected through a low jitter, low skew, and low noise Global Clock network. Though, inherently there are slightly different propagation delay between the input pin signal and the TDLs, or between the clock pin and the latching clock at the TDLs. The relative variability is due to variations in the chip propagation delay, number of loads for each branch, routing, placement, etc. The calibration processes measure and provide compensation for such timing offset. For calibration purpose the SCKCtr is visible to all TDL encoders and used as reference for alignment.

### Fpga Implementation.

The Following Abbreviations are Used Throughout this Specification:

TDL=Tapped delay line. TDL translates the time delay it takes for a digital signal event (at its input) to propagate to the taps changing polarity. It is based on the proportional relation between the time and the distance which is marked by quasi equally spaced taps.

TDLS=Tapped Delay Line Snapshot captures the taps of a TDL with a snapshot Clock into a register, where each bit represents a tap, The snapshot Clock latches the logic level of taps as the front edge of the signal advances along the TDL, changing taps logic level. Practically it converts time to propagation distance, assuming that propagation has constant speed and taps have quasi equal delay. Ex: assuming the entry point is at the left, the signal is a rising edge, and the delay between the first three taps is 5, 8, 6 ps then if the SCK latches 111000 . . . 0 then the event happened at the time of latching edge of the clock minus 19 ps.

TR=Thermometer reading—the snapshot of a TDL represented as strings of adjacent logic levels of 1 or 0. Transitions may be noisy if 0 and 1 mingle, into a “bubble” patter (Ex 111110100000). Snapshot=Capture of a TDL Status

BTW=blind time window, or the blind spot interval is a time interval where no signal transition can be captured. A continuous TDC has no BTW.

DR=dynamic range, the maximum time interval that can be measured.

DT=Delay Tap, time it takes for a signal to propagate between to conf770secutive taps

TR=Tap Register.

E-TDC=Ergodic TDC. Contains NumInst of TDC.

ECARRY=superposition of Carry chains used by parallel TDLs, resulting in a larger pool of taps, allowing a denser selection of equally spaced taps (max taps in a CARRY chain is numTDL), without performing individual CARRY chain tap selection, which eliminated numTDL constraints.

Event=signal transition at the pin of the device, which is timestamped by a clock.

Etap=the equivalent tap, resulting from the interleave of taps from multiple TDL or TDLSec. The average Etap is the average Tap divided by the number of TDLS captured i.

EsumTDLSecS=the Sum of all the taps (each having a logic level 0 or 1) of all the valid TDLSecS, latched by the same phased SCK.

EsumTDLSecTS.=the Sum of the TS generated by all NumInst instances of a TDLSec.

NumInst=total of TDL elements of an E-TDC (practical range is between 16 and 256).

numSCK=total number of clocks.

numSec=total number of sectors for a TDC structure. It is also the same for an ETDC.

numTDL=number of TDL latched by one clock

Q=quad sector of a TDL.

nTDL=TDL number n.

nTDLSec=a sector of nTDL (marked also as Q1, Q2 for example).

DTtotal=total number of Delay Taps in a TDL.

PhOff=phase offset for a TDLSec, representing the propagation delay of a signal transition event between a common reference point and the first tap of a TDLSec.

Absolute Calibration=a process used to find the relation between a timestamps measured and the absolute physical timestamp at the pin of the FPGA device

NomDel=statistically calculated nominal delay for each DT from calibration data

eSumTDLSecTS=the sum of timestamps corresponding to TDLSec with same input delays aligned to the input of TDLs having a same latching clock.

eSum( )=Sum over NumInst terms used by ETDC.

AvgTS=eSum( )/NumInst

Compactor=logic block that d filters t only Valid event transition data.

ESum(phOff)=Sum of phase offset for all NumInst.

PhOff=delay between the a common reference and an input of a TDLSec. Each ETDC has one PhOff.

PhOffnp=logic low SCK time, between the falling and the rising edge of Tsck.

PhOffpn=logic high SCK time, between the rising edge and falling edge of Tsck.

PhOffTDL=phase offset of a TDL representing the delay between the pin and the input of TDL.

PhOffSec=phase offset of a TDLSec representing the delay between the device pin and the input of a TDLSecl.

pSCK=the positive edge of SCK used as arbitrary reference for phase.

pSec=pSCK latched sector of pTDL.

SCK=snapshot clock. The main system clock, or the reference clock for the TDC, which is incrementing the clock counter.

phSCK=phased SCK, different phases of the SCK latching the TDLSecS or clocking SCKCtr.

SCKCtr=the raw counter of SCK periods.

pSCKCtr=the raw counter driven by pSCK, SCK rising edge, for the two latching clocks embodiment

nSCKCtr=the raw counter driven by nSCK, SCK falling edge t, for the two latching clocks embodiment.

Sec or Sector=a subdivision of a TDL comprising one or more groups of taps.

Slice=split of a sector in subsections.

sumTDLS=sum of all the bits in a TDLS.

sumTDLSecS=sum of all the bits in a TLDSec snapshot.

SCS=sweep clock step, is the change in CCK phase relative to SCK for one SCK period, due to the slight, difference in frequency, which is designed to be proportional with the precision of the calibration. Also known as progressive, or traveling wave.

Transition=change of the logic level in a sting of bits (Ex 111000). A transition can be noisy when has bubbles (Ex: 111010000)

TDC=time to digital converter, here refered as a budling block of an ETDC.

TDLS=TDL snapshot, in the form of thermometer reading.

TDLD=TDL delay.

TDLTS=TDL timestamp.

TS=timestamp relative to the TDLCtr SCK.

TSS=time stamp sum

Tsck=period of the SCK.

TDLSec=sector of a TDL. The smaller entity used to measure time. A TDL comprises one or more TDLSec. As example a TDL is split in two TDLSec marked as Q1, Q2. Another TDL is split also in two TDLSec market as Q3 Q4. The are further latched into TDLSecS by the positive edge of clock marked pSCK or the negative edge of a clock marked nSCK. Depending on the name of the latching clock the TDLSec are named more specifically as pTDLSec or nTDLSec. (FIG. 6).

TDLSecTS=local timestap Relative to the beginning of TDLSec, indicating the time of transition relative to its latching SCK (661 for 616 pTDLS), (621, for 612 nTDLS).

TDLSecS=TDLSec snapshot (thermometer reading) by its latching clock.

TDLSecSE=binary encoded TDLSecS relative to the local TDLSec bounds (from 1 to the maximum number of taps).

TDLSecTS=TDLSecSE retimed to reference the SCK bounds, of an SCK period counted by the SCKCtr. The time offset between the TDLSec and TDL is added to the TLDSecTS.

TDLSecSla=slice of a TDLSec.

TDLSecSlaS=snapshot of a TDLSecSla.

Valid=a flag indicating a transition at the current TDLSec or at its boundary with another.

Valid Transition=An actual change of a signal polarity, creating an event which is timestamped and sent to the network interface.

vTDLS=curret TDLS has a valid transition.

vTDLSecS=valid TDLSec snapshot.

vCtr=Counter of all TDLSec in an ETDC which produced a valid timestamp, vTDLS

vSum=Sum of all TDLSec in an ETDC which produced a valid timestamp, vTDLS

TO=time overlapping section—a section of taps of at one end of a TDL and another section of taps at the other end of another TDL which capture the same transition signal (FIG. 17 Example: a first tap of 1712, marked 1721 captures a signal also captured at the tap R of TDL 1713 by 1702 edge of the another clock)

### 5. RELATION BETWEEN TDL AND SCK PERIOD

The maximum clock frequency is limited by the chip technology and routing quality. Meanwhile the carry chain used as a TDL has a total delay shorter than the minimal achievable period of its latching clock, for example SCK. This results in blind spots, resulting in events being missed if only one TDL is used with SCK. Each clock can latch only the signal which reached the TDL input at TDL delay before the edge of the clock, and other earlier signal transition events would be missed. One solution is to have additional TDLs, serially chained to cover the blind spot and ensure a total delay at least equal with the period of SCK. But the delay of interconnection between TDLs is significantly larger than the regular tap delay. Such chaining would result in unacceptable nonlinearities. Other alternatives to extend the time interval covered by multiple TDLs is to either have different propagation delays between the signal pin and individual TDLs and using the same latching clock or having the same propagation delay between the input signal and the individual TDLs but latch them with clocks having a phase offset. The first option is difficult to implement over general clock (GC) lines, especially as current tools do not provide reasonable user access and control for the GC routing. An embodiment may se parallel TDLs driven by a minimally skewed input signal over GC lines, and having the TDLs latched at different times, by different phase offset clocks. Two shifted latching clocks of two TDLs with the same input is equivalent with delaying the input signal of one of the TDL, by the offset between the latching clocks, and performing a numerical processing of the data as if taken with a virtual TDC with longer delay and higher number of taps. Embodiments may have different topology solutions as shown in FIG. 16, 17, 18, 19.

In some instances, the TDL of an ETDC may be in the same FPGA clock region for the lowest skew on the Global Clock lines.

### Time Relation Between Clock, Signal, and Propagation Delay for a Signal Transition Event to be Captured on a TDL.

The signal at the input of TDL is latched on the TDL registers if it arrives no sooner than the active edge of the clock minus TDL delay, and no later than the active edge of the clock. Assuming there is a propagation delay between each TDL signal and the FPGA pin of origin, it results the formulas:

$$t ( CLK ) - delay ( CLK ) > t ( event ) - delay ( event ) > t ( CLK ) - delay ( CLK ) - delay ( TDL ) \\ 0 > t ( event ) - t ( C L K ) + delay ( CLK ) - delay ( event ) > - delay ( TDL ) \\ 0 < t ( C L K ) - t ( event ) + delay ( event ) - delay ( CLK ) < delay ( TDL ) or \\ 0 < t ( C L K ) - t ( event ) - ( delay ( CLK ) - delay ( event ) ) < delay ( TDL )$$

Wherein t(event) and t(CLK) are the time of occurrence of event and CLK at the TDL, delay(CLK), and delay (event) are the propagation delays between the pin and the TDL, and delay(TDL) is the total delay of the TDL. The “delay” terms are constants for each TDL, while “t” are variables

For simplicity reasons, and without losing from generality, it may be assumed that the propagation delay constants cancel each other: delay(CLK)=delay(event).

Accordingly t(CLK)>t(event)>t(CLK)−delay(TDL), To have continuous coverage any event between consecutive CLK periods should be captured (without losing from generality it is possible to reduce the domain of the variables to a clock period, such that any t(x) satisfies: 0<t(x)<T). Any event within T(CLK) should be captured including outside the bounds of the inequality above. Continuous timestamping requires that delay(TDL)>=T(CLK), the period of the latching clock. The T(CLK) cannot be practically reduced to delay(TDL) which is <1 ns. Therefore the only option is to virtually extend the delay TDL (to avoid coverage gaps), by using another, slightly overlapping TDL captured with a phase shifted CLK. Some implementations may use the opposite, falling edge of the same clock, resulting in an equivalent T(CLK)/2 delayed TDL latch for the T(CLK)/2 delayed event signal.

Intuitively, to capture all events on the same TDL the period of the CLK must be smaller or equal than the delay(TDL). The carry chain may be used as TDL in some designs described herein because of the low noise and small interlap delay, and are therefore faster compared with the fastest practical latching clock.

It is obvious from the formula that a time shifted clock shift(CLK) allows capture of an event shifted by the same amount shift(event)=shift(CLK), while the value of the formula remains the same, within the same boundaries. Therefor using both edges of the CLK for a TDL latch, extends by half of CLK period the event capture window.

In some embodiments equally spaced phase offset clocks may be used for TDLs connected in parallel to the event signal pin through global clock distribution lines, having minimal routing delay variations. FIG. 19 shows the time intervals associated with each TDL snapshot covering a full SCK period. The TDLs, despite have a propagation delay shorter than the period of the latching clock overlap and avoid blind spot intervals, BTW.

One embodiment determines the time an event enters TDL, before the edge of the clock latching the TDL by counting the taps the event propagated on the TDL. For the TDL latched by the positive edge of SCK, pSCK the encoded local time is pTDLTS, which is associated with the value of the raw counter, SCKCtr which is incremented by the same pSCK. The pTDLTS occurs before the SCK edge increments SCK counter, and should be subtracted from the period of the SCK, Tsck to provide the fractional time relative to the previous SCKCtr value. The events latched at a TDL by negative SCK edge, nSCK, and encoded as nTDLTS, has to be referenced to the same SCKCtr clocked by pSCK. Therefore, the nTDLTS has to be shifted by the phase offset between the latching clocks, to change the reference timing from nSCK to pSCK clock transitions. Then it can be subtracted from Tsck to represent an addition to the previous clock period. Another embodiment performs the same for retiming of the TLDSecS in between the time domains of the latching clocks.

Some embodiments disambiguate the situation when the same signal event is captured twice by TDLSec in different time domains, with different latching clocks, for example at pTDLSec and a nTDLSec (sectors of pTDL and nTDL) in their common time overlapping section. The technology divides each TDL into sectors and each sector can independently determine a signal event transition and its timestamps, TDLSecTS, relative to the period of the reference clock, SCK, and SCKCntr. By design, distance between same polarity transition cannot be shorter than twice the delay through a TDLSec. At maximum, only one transition is expected on each TDLSec. A signal event may generates two timestamps with identical or very close value, in overlapping time section of adjacent TDLSec. Even if the values are almost identical this can be considered an ambiguity. The duplicates increase the line bandwidth by the ration of the overlapping sections. Duplicates are identifiable as both timestamps will have the same transition polarity and for overlapping taps of TDCsec. Also their values would be closer than the minimum expected interval of the signal events. The SW can easily identify and average the two timestamps produced by different TDLSec. The effect of letting such ambiguity uncorrected is an increase in the bandwidth by the ratio of overlapping time and the period of the latching clock. and the period of the latching clock.

An embodiment of the technology eliminates the duplicate timestamps at the encoder, by converting one of the duplicates TDLSecS to the other TDLSecS time domain (as defined by the respective latching clock) and performing an average of the two measurements in the same TDLSec, of simply by discarding one of them. As the overlapping happens between the opposite end points of TDLs latched with different clocks additional processing FPGA logic can be limited for the corresponding TDLSec pairs. For example in FIG. 17 the AD segment of pTDL 1712 (between 1721 and 1723) captures the same event latched on the segment RP of nTDL 1713. Because the pSCKCtr changes on the pSCK (1701 or 1703), both AD and RP segments are in the same clock period. A TS in RP is measured relative to TDLSec Q4 than the segment NR has to be subtracted from TDCSecTS and added to TDCSecTS of Q1.
A similar situations applies to double timestamps captured in the segments DC on pTDL 1714 (between 1725 and 1727) and segment MR on nTDL on 1715, with the difference that no the pSCKCtr incremented on 1704 o4 1706 therefore the segment DC is timed in the next clock period. Accordingly the average or suppression of one of the TS should be done across two adjacent time periods of SCK. For example BD can be added to TS in Q3 and result can be averaged in Q2 DB can be subtracted from TS in Q2 and averaged with the TS in Q3 of the previous SCK period.

When TLD delay is shorter than the period of the latching clock, Tsck the TDL registers can see only the signals which entered the TDL within a certain window before the active edge of the latching clock. The difference between the clock period and TDL delay is a blind interval, where no signal can be captured. Additionally variability between the signal propagation delay between the pin and the TDL inputs, variations between TDL delays, and variations of the phase of the associated SCK latching clock of TDLs may modify the phase and size of blind interval of the actual signals at the FPGA pin, relative to the latching clock of each TDL. Accordingly, event signals may be latched only by some TDLs.

An embodiment of the technology counts the number, VCtr of Valid TDLSecS captured during a Tsck by analyzing the TDLSecS patterns. If the sum of all TDLSecS bits is different from either null or total number of bits (also called compact pattern), or the sum of adjacent TDLSecS are compact patterns but with different (or complement) sum values then there is a transition. When TDLSec and TDL are shorter than the latching clock period, it is uncertain how many of the TDLSec are capturing an event. This depends on their relative delay to the latching clocks, delay to the common pin, and the noise. An embodiment determines the number of valid TDLSecTS and their sum. Another embodiment doubles the values of TDLSecTS which do not overlap with other TDLSecTS, and add them with the simple sum of overlapping TDLSecTS to achieve a correct average of valid TDLSecTS. Other embodiment clears the invalid TDLSecTS or TDLSecS to allow a simpler unconditional sum to operate as an addition of only the valid TDLSecTS or TDLSecS. Additional embodiment performs undifferentiated sum of TDLSecTS or TDLSecS when it is guaranteed by design that at any point of time when the sum is performed there is fixed number of TDLSecTS or TDLSecS. Other embodiment performs first the sum of TDLSecS and then the binary encoding TDLSecSE, while another embodiment performs first the binary encoding TDLSecSE and then the sum.
One embodiment represents the delays as a number of delay taps. Another embodiment converts each TDL tap into its actual time delay.

### 6. ARCHITECTURE

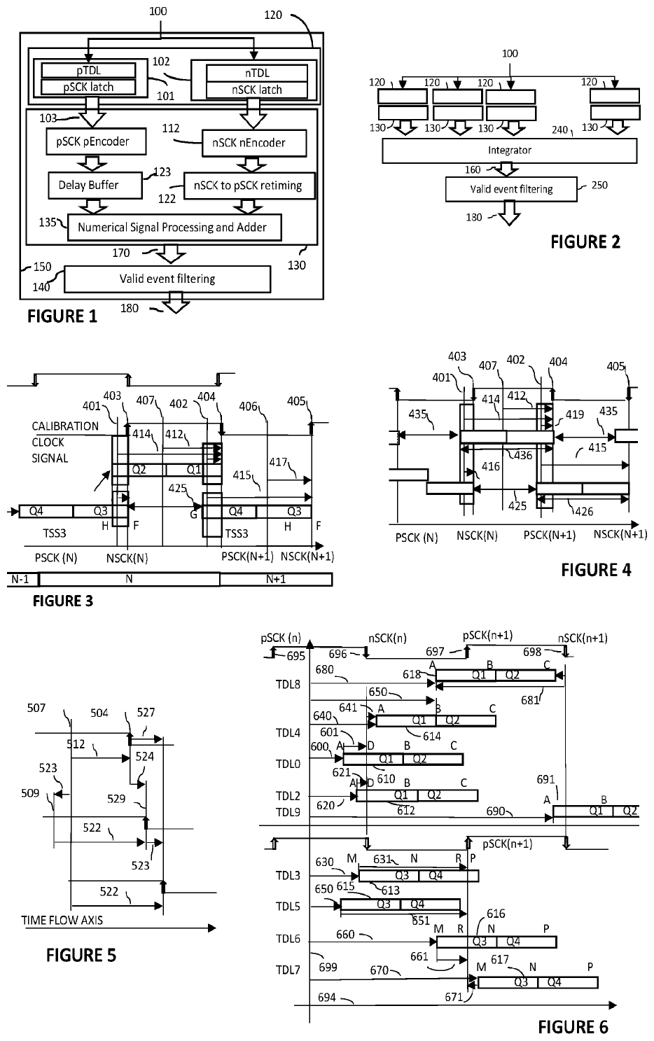

An embodiment, as illustrated in FIG. 1, comprises a plurality of TDCs (150) or a plurality of TDLSec (101, 102, 120), or a plurality of encoders (130). In some embodiments each TDLSec may have a corresponding encoder. Some embodiments may have an adder for the TDLSec located on TDLs with the same input signal, and having the same time offset relative to the pSCK. An embodiment generates a plurality of timestamps corresponding to a plurality of TDLSec, during each SCK period. A plurality of TDLSecTS associated with one event signal, and corresponding to a same time interval relative to the SCK period, are summed or averaged across NumInst TDCs, to generate an eSumTDLSecTS or an E-TDC timestamps (180) corresponding to an actual transition of the input signal (100). The average is calculated by dividing the eSumTDLSecTS by the VSum which results in enhanced precision, accuracy, and lower noise.

Each TDC comprises a tapped delay line (TDL) a binary encoder, an adder, and an event filtering block, or compactor (FIG. 2).
The TDL's taps are continuously latched into registers by an edge of one or several clocks. One ETDC embodiment comprises a plurality of TDL associated with a plurality of clocks, with a plurality of phase offset relative to the SCK. A clock latching edge takes a snapshot of the TDL, TDLS, or a snapshot of TDLSec, TDLSecS. If the PD of the TDL is shorter than the period of the clock, a plurality of multiphase latched TDSs allows coverage of blind intervals (FIG. 4, 425, 435) of a TDL by other TDL (FIG. 4, 426, 436), clocked such that they have an active capture window (426) overlapping the blind intervals (425).

Another embodiment has taps from one TDL latched by a plurality of clocks on a plurality of registers. For example one TDL shorter than SCK can be latched on both SCK edges which creates a second TDL delayed by about half of the SCK period, which convers the blind interval and allows capture of any event during an SCK period. The same selection of taps or interleaved taps can be used for the two registers. Another embodiment uses separate TDL for each register and latching clock pair.

Another embodiment uses a plurality of TDCs each latched by clocks with different phase offset to SCK, and a raw counter, clockCtr for each. Each TDC generates timestamps having a known phase relation with SCK. When an event is captured simultaneously by several clocks, their phase relation allows timestamps retiming the SCK time zones, and perform their averaging.
The building block which generates one individual measurement is a TDC. Without losing from generality, can consider that the TDC is based on a plurality of Tapped Delay Lines (TDL) and the TDC is a continuous acquisition TDC, which has no dead time at any time.

E-TDC consists of a plurality of TDC. The different delays of individual TDLs, and the phase offset between different clocks are determined through calibration and compensated through a Numerical Signal Processing (135) block. The inherent noise and routing delay adds uncertainty on which, and how many TDCs will actually capture Valid timestamps. To eliminate this uncertainty, a final analysis (140) is performed and only the Valid TDLSecTS timestamps are preserved (180) and transferred out of ETDC.

One embodiment performs offline calibration to selects most evenly distributed taps of TDL. Some embodiments perform linearization of TDL taps, for better precision by replacing the tap number with the actual measured or calculated delay, which requires a few additional bits. (Ex: the representation of 120 TDLSecS taps requires 7 bits. To provide a tap accuracy of 1/512, must add 2 more bits for a total of 9).
In some embodiments, chained carry lines of an FPGA may be used for the TDL (101,102) of a TDC Another embodiment may use custom ASIC delay lines, or even discrete delay lines. In one embodiment the D input of a FF is connected a plurality of TDL taps.

One embodiment has TDLDs bigger than the clock period, all TDL will capture any transition. The number of timestamps generated for each clock will be equal with the number of TDLs. Regardless of individual TDL routing delay, the sum of timestamps implicitly comprises the sum of their routing delay from the pin. It results that there will be only one phase offset compensation for the E-TDC. This simplifies the Numerical signal processing block.

For present FPGA or ASIC technology, the global distribution clock network has a delay variation much smaller than the minimum clock period. There is no ambiguity resulting from routing delays of more than a half of a clock period. Therefore, the count of the clock can be determined at any TDC. The E-TDC has one raw counter which is distributed through a register pipe throughout the FPGA.

Some embodiments may use a pair of TDL clocked in antiphase, each TDL with a pair of sectors to implement an ETDC.

Q1 and Q2 are the Sectors of a nSCK latched TDL, nTDC. Each sector has two slices E and W. Q3 and Q4 are the Sectors of a pSCK latched TDL, represented in dotted lines. Each sector has two slices E and W. Without losing from generality, will consider the case of two sets of TDL each clocked by clocks with a 180 deg difference (antiphase), or same clock, but TDLs are latched on opposite edges. 694 is the time axis, and intersection with 699 is the event signal received at the device pin. 640,600,620, 630, 650, 660 are the propagation delay between the pin the input of the TDL, PhOffTDL. The 610 to 618 are the active time windows when TDL0 to TLD8 can capture a transition. It is determined by both the delay from the event signal on the pin (699) and the delay of the active edge of SCK, which latches TDL status in its local registers, as TDLS.

TDL 0,2,9, and 4 are clocked by the nSCK. TDL 3, 5, and 6 are clocked by the pSCK. 601 is the time between the signal arrival at the input of TDL0 and the nSCK negative edge of the sampling clock which is captured as TDLSecS. The interval AD is the difference between time D and time A. AC=tC−tA is the total delay of the nTDL (TDLD).

The nSCK latched TDL, or nTDL, when the signal arrives at nTDL input within less than TDLD or tC-tA.

Because TDLD is >time between the nCLK and pCLK, npT or pCLK and nCLK, pnT.

Without reducing from generality, will arbitrarily consider that TDLD is the same for all nTDL.

An event is captured (after the delay 600, 620) on an nTDL, at D if it occurs no sooner than TDLD time before nSCK (in contrast 681>TDLD; 680 is not captured), and no later than nSCK. (640 is not captured).

The pSCK latched TDL, or pTDL is defined by the interval MP. Without reducing from generality, will arbitrarily consider that TDLD is the same for all pTDL; An event is captured on a pTDL, at R if it occurs no sooner than TDLD before pSCK (631 captured, 651 not captured), and no later than pSCK (671 not captured on TDL7). If an event reaches TDL before nSCK(n), but after pSCK(n) it is captured on TDL0, TDL2, represented as 601 and 621. It is not captured on TDL4.

Each of the parallel TDL may receive the event signal to be timestamped at a slightly different time. As a result, some of the TDLs in a group may not receive a signal, which is close to the edge of the SCK. For example, TDL4 with signal delay 640 will not be captured as it arrives to the nTDL after nSCK. But it will be captured by TDL0, TDL2.

Some events will be captured on both pTDL (630) and nTDL (620). The readings will differ by the phase offset between pSCK and nSCK, and by the difference between the propagation delay between pin and the input of the TDL (difference between 620 and 630) In conclusion, at any time a signal should be captured by half of the total TDL and for certain relative timing between signal and clock may be captured on all the TDLs. To do the correct average, the ETDC engine determines the number of Valid TDCS, which were summed

### 7. SWEEPING CLOCK CALIBRATION

The default accuracy and precision of the TS is improved by calibration.

Calibration measures the time delay for each tap and the event signal propagation delay between the device pin and each TDL's input, PhOffTDL. Variability of PhOffTDL reduces the accuracy of the TDLTS.

The accuracy and precision of a typical clock oscillator is better than 50 ppM. A TDL or TDLSec has delay of less than 1 nS will see delay variations within 50 fs, which are practically negligeable for the purpose of tap delay measurements. Some embodiments may correct such offsets by synchronization with network algorithms, for example the General Timing Synchronization, GTS, or the PTP.

Some embodiments may measure the delay of the taps of a TDL using a Sweeping Clock method, by driving the input of the TDL with a signal, CCK that is very close (in the range of 10E-4 for sub pS accuracy of calibration) to the SCK, or its submultiples.

For every SCK, the CCK is changing its relation to SCK by a Phase Progression time value representing the small difference between the periods of CCK and SCK. The number of SCK counted by SCKCtr between the change in polarity of two consecutive taps multiplied with the Phase Progression provide the signal propagation delay between the two taps.

Depending on the general level of noise and the desired accuracy, an embodiment uses a rage of Phase Progression of 0.1 ps to 0.5 ps. Another embodiment uses the minimum difference between an SCL˜=599.9 and the CCK˜=300 MHz frequencies, which can be generated by the board circuits. One embodiment has CCK and SCK with the same frequency (or an integer multiple) but generated from asynchronous oscillators on the board, having an inherent offset of 20 ppB. The Phase Progression is determined by dividing the period of the clock by the number of SCK counted for the CCK to reach the same tap of TDL. For a SCK period of 1.66 nS it translates into 1.66 2E−5=3.2E−9*1 E−5=0.032 pS. For 300 MHz it is double=0.064 pS per 300 MHz period, which is added to the Sweeping Clock Step, SCS.

For one embodiment using latest FPGA families and a global clock (GC) network for routing of event signals from pin to the TDLS, the routing delay variation between PhOffTDL instances is smaller than a fraction of the SCK period, and all TDLS will snapshot the event signal within that fraction of SCK period. The variations from routing delays and latching clock delays are measured through calibration and the TDSSecSE or TDSSecTS are corrected at 135. While the event signals occur on a continuum basis the processing is performed during discrete clock periods, delineated by the SCK. In some embodiments, TDLSecS valid transitions snapshots taken with different clocks are binary encoded, retimed to the pSCK reference edge, and Summed as EsumTDLSecTS or TSS. In some embodiments, sums of all the TDLSecTS terms in a VSum variable. The average of the timestamp of a TDLsec is performed by dividing the associated TSS by its VSum.

One embodiment where a plurality of PhOffTDLSec (690) have values longer than the full clock period, Tsck, and the same event is captured by the plurality of associated TDCs in different clock intervals (691, 621, 631), PhOffTDL are measured for each TDLSec, the processing pipe places the snapshots of such TDL in the proper SCK period, to match with the other snapshots generated by the same event.

Another embodiment determines or knows the value of the Phase Progression and is counting the number of SCK periods necessary for CCK edge to travel between each tap (observed as a change in polarity of the tap) can determine the delay between the first tap and any other tap of the TDL, and subsequently associate or replace the tap number with the actual delay. Moreover, during progression, the order of the taps is the order the signal wave reaches the tap. An embodiment reorders taps sequence in the order they actually change polarity as the CCK propagates through the TDL. Another embodiment automatically determines the tap order through the sum value which is agnostic to the location of the tap. Further is selects a subset of the taps such that there is a minimum variation in the delay between adjacent taps. The calibration process measures a plurality of TDL Carry locations on the chip until finds the best Carry locations for equal delays for adjacent taps and optimal phase offset between TDLs.

### 8. OFFLINE CALIBRATION AND SELECTION OF TAPS

An embodiment selects the taps of a TDL from the taps of a CARRY chain such that the tap to tap delay is between a maximum and a minimum value corresponding to the precision specified for the design. The calibration measures CARRY chains from the chip, and selects the ones which are can provide the maximum and minimum selection.

Another embodiment selects the adjacent Carry units from the CARRY chain down to a total propagation delay longer than the minimum phase offset between the latching clocks (the minimum of all AC and MP should be bigger than the minimum between 696 to 697 and 697 to 698 clock edges. See FIG. 17). For example, Xilinx FPGA has one Carry block per one CLB unit and typically there are a of 30 Carry blocks in a homogenous CARRY chain from CLB 0 to 29. One embodiment may select only a subset, for example from CLB 2 to 29.

Another embodiment selects the number of taps per slice and sector by having their total delay smaller than the minimum pulse to be detected. Accordingly, there will be at most one transition per sector. This feature reduces the complexity of the design.

Further embodiment measures the tap delays of TDL placed at several locations on the chip, in physical order as indicated by the FPGA manufacturer (FIG. 6, 601) to select equal delay tap intervals for the highest precision. The taps are sorted based on the total delay to each tap. (602), resulting in a new tap order. Only a fraction, measured at about ¼ of the taps with almost equal tap to tap delay, are selected. The taps with very close delays may be skipped.

An embodiment performs the sum of all the CARRY chain taps for the plurality of TDL latched by the same phased SCK (all the available taps may be included, before any selection is made), and calibrates the delay for every tap. This provides more options for selection of the taps and generates equal delay in between ETDC taps. As the overlapping is physical, there would be lower tap densities at the ending points. Though the overlap with adjacent TDLs using a diggernt clock will provide a similar, uniform density for the virtually continual TDL.

As an example, first select 2 taps sequence from two, 4 tap TDL with the delays 4, 5, 10, 20 and 7, 8, 12, 16, then apply two initial constraints go get equally spaced taps among each TDL resulting in 10, 20 and 8, 16, which superimposed generates the ETDL outcome 8, 10, 16, 20. If the sequence is reverse by first superimpose, resulting in interleaved TDL taps, and then perform the selection, we obtain the following consolidated delays: 4, 5, 7, 8, 10, 12, 16, 20. There are no constraints, and we have a larger selection of options/combinations. The ETDL outcome is more diverse and better balanced: 4, 8, 12, 16 or 8, 12, 16, 20.

### 9. RUNTIME CALIBRATION

In runtime calibration mode, a calibration clock, CCK signal replaces the input from the device pin. An embodiment uses a Clock Multiplexor Buffer in the proximity of the pin to minimize variations in the PhOff propagation delay, resulting from GC routing between the pin and the TLDSec.

Another embodiment measures and calibrates each value of the sumTDLSecS (sum of the all TDLSec taps which can capture the same signal event).

Each TDLSec of a TDC or ETDC has a different PhOff to the input pin, or any other common point, and each value of the sumTDLSecS includes the same specific taps because the sumTDLSecS is monotonic as the CCK propagates through the SDLSec, it changes one by one the logic level of the taps (in the absence of noise). Therefore, it is possible to measure the actual time delay for each value of the sum (summing individual TDLSecS tap number of the local transition). For situations when the noise disturbs the monotony of the sumTDLSecS by one or two counts represented missed taps at the individual TDLSec level, which taps are spaced by much bigger delays than the ETDC superposition taps, they generate the same numerical error on the EsumTDLSecS of the interleaved taps of the ETDC, but at ETDC the tap to tap delay are much smaller than the tap to tap delay of an individualTDLSec) by a factor of NumInst/NumSCK.

Some embodiments may measure and calibrate the sum of all the sumTDLSecS of an ETDC, EsumTDLSecS. The sum of sumTDLSecS monotonic functions, EsumTDLSecS is also monotonic. The Sweeping clock calibration determines the relative delay between two EsumTDLSecS consecutive values by multiplying the difference between the corresponding SCKCtr values and the known value of the Phase Progression. For example, if it takes 10 SCK between two consecutive changes in the EsumTDLSecS value (for example from 123 to 124), and Phase Progression is 0.1 pS then the delay between the Etap 123 and Etap 124 is 10*SCS=1 pS. Another embodiment forces all invalid (when no transition detected) sumTDLSecS to 0, to have an indiscriminating addition pipe. This provides less complexity and higher clock speed.

### 10. BINARY ENCODER

TDLSecS is a thermometer reading, a plurality of 0 and 1 compact sections and transition in between.

The binary encoder provides the tap number where the transition occurs in between compact sub strings. It converts the “thermometer” strings of same polarity bits into a number indicating the tap number of the transition between the string of 0s and the string of 1s relative to one end of the TDLSecS, chosen by convention. The transition can be noisy, comprising “bubbles”, multiple 0,1 sequences, which are approximated by the encoder to a one single transition, TDLSecSE.

The sum of all the bits in a TDLSecS can be performed as a parallel, one clock addition of all, one bit terms, in numbers equal with the number of taps, or a sequential addition bit by bit, or a combination of both. The parallel processing pipe has the advantage of continuous operations. The processing steps are implemented as a multistage pipe where TDLSecSE is generated every clock cycle.

A sequential adder may take a number of SCK up to the total number of bits, during which time there is no new acquisition. Though it requires logic.

An efficient encoder implementation is highly dependent on the chip HW architecture, and the available resources. The use of embedded DSP hardware cores significantly reduces combinatorial logic. For example, an embodiment divides the TDL in two TDLSec, and each TDLSec in smaller slices to optimize the use of combinatorial resources for two or three bit terms (base 4 or base 8 numbers) and DSP resources on the chip for wider terms or base 16 numbers. An additional embodiment uses random delays between the device pin and the TDL input, selected to avoid blind intervals, and only one phase SCK.

### 11. THE SUM-BASED ENCODER

The Sum Method adds the value of the TLDSecS bits regardless of their location or order on the TDLSec. The out of order tap transitions during signal propagation through TDL are irrelevant. The sum method (SM) of determining the transition is ambiguous because there are bit pattern combinations producing the same sum, therefore additional logic is required to determine the polarity of the transition Ex: 111100 is not distinguishable from 001111 or 100111.

Disambiguation of edge of the transition: An embodiment provides disambiguation between the positive, p, or negative, n signal edge transition, by comparing the sum of two sectors, and considering the constraint of minimal pulse width longer then a sector delay and the constraint that adjacent pulse edges are complementary. When the sum of adjacent TDLSecSE is smaller than total TLDSecS bits than the high pulse cannot be in between the TDLSec as it would be smaller than allowed. Therefore there must be a null pulse, longer then the TDLSecS total bits, at the mid section. Ech TDLSecSE indicates the exact tap of the transition.

Ex: 5=TDLSecSE Earlier Sector and 2=TDLSecSE Later Sector and TDLSecS bits=8 indicates a 1111100000000011 pattern.

If transition happens at overlapping between two TDLs latched by adjacent clock phases (Ex: n and p, where SE is the last on nTDL) it is possible that the later latched TDL could have one or more transition bits, TB or both TDL could have TBs because noise and/or because the signal arrives first at the second latched TDL than filling all the bits on the first TDL.

The physical and temporal sequence of taps of a TDL is different. The sum method, SM is agnostic of the location of the added taps, therefore it is agnostic to the sequence in time the taps change logic level when the event signal propagates through the TDL. Accordingly, rearranging the taps in the order of signal propagation is not necessary. For example, assuming a 6 bits TDL, with the physical order 1, 2, 3, 4, 5, 6 but the time delay order 1, 2, 4, 3, 6, 5 will read a traveling wave as the sequence 100000, 110000, 110100, 111100, 111101, 111111, while the SM will produce the sequence 1, 2, 3, 4, 5, 6 equivalent with 100000, 110000, 111000, 111100, 111110, 111111.

Assuming that 1) the signal happens shortly before the pSCK, and 2) that the nTDL first two bits come earlier relative to nSCK, than bit 5 of pTDL relative to pSCK, but 3) later than bit 6 of PTDL. A possible relevant sequence of the two would be 111100 000000, 111101 000000, 111101 100000, 111101 110000, 111111 110000. The sum pair SE, SL would be 40, 50, 51, 52, 62, and their sum 4,5,6,7,8 which describes a monotonous progression of the sweep clock, traveling wave. If the sum of either TDL is max or min (compact TDL snapshot)

The edge is p because SE>SL. If it is a rising edge, the timestamp is equal with the sumTDLSecS. Otherwise, it is the complement relative to the number of taps. Raw clock counters can be maintained per each clock taking snapshots of TDLs. Example: Two counters can deliver the raw count, one incrementing on the pSCK having the LSB=0 for the other one incrementing on the nSCK having the LSB=1. The clock duty cycle is not perfect and creates an asymmetrical interval in between TB01 and TB10 (Transition bits).

A Valid TDLS captures a transition between strings of 0 and 1, which is inherently noisy because of metastability, threshold variations, local voltage variations, skew in the arrival clock, technology dispersion, and other reasons. There will be a random pattern of alternating 0 &1 instead of a crisp transition between all 1 and all 0 sequence of taps.

An embodiment solves the noisy transition issue by making the sum of all taps sumTDLS. The sum indicates the tap number where the transition is most likely to occur between the sequence of 1 and the sequence of 0.

The sumTDLS is split for efficiency and performance in smaller sectors sums, TDSecSE. This allows multiple timestamps generated for one TDL and narrower minimum pulse width which can be timestamped on both edges. For example, if TDL has 120 taps, a TDSec may have 60 taps. The ETDC adds the plurality of TDSecSE or TDSecTS, and also counts the number of Valid TDSecSE, (or sum vTDLSec). An embodiment compensates for the PhOff of each individual TDL, or TDLSec input. Other embodiment performs the addition of TDLSecSE for each phased SCK.

ETDC determines a timestamp in each sector of TDL using a shared lathing clock. Total number of timestamps per SCK generated by ETDC is numSec.

As example if the TDL has two sectors, TDLSec, the commutativity and associativity property of the addition allows performing of tap addition, TDC addition, and phOffset addition for each sector or TDC, in any order, as the final result is the addition of all taps aligned to a common reference. The sum based encoder cancels the transition noise. The transition between the all 1 and all 0 compact sequences can be noisy, showing as a random sequence of 0 and 1; Example: 111110100110100000. This is implicitly solved in the encoder which counts all “1” or all “0” for a sector of a TDL and such provides a crisp position of the transition. The sum, TDLSecSE in the example is 9. Which is the equivalent of 111111111000000000.

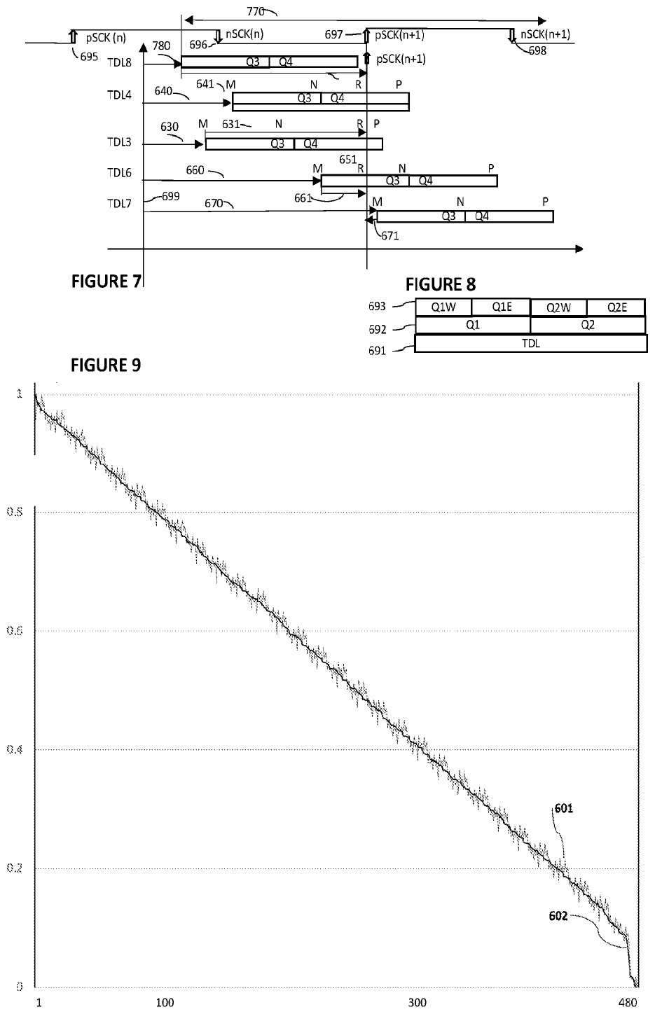

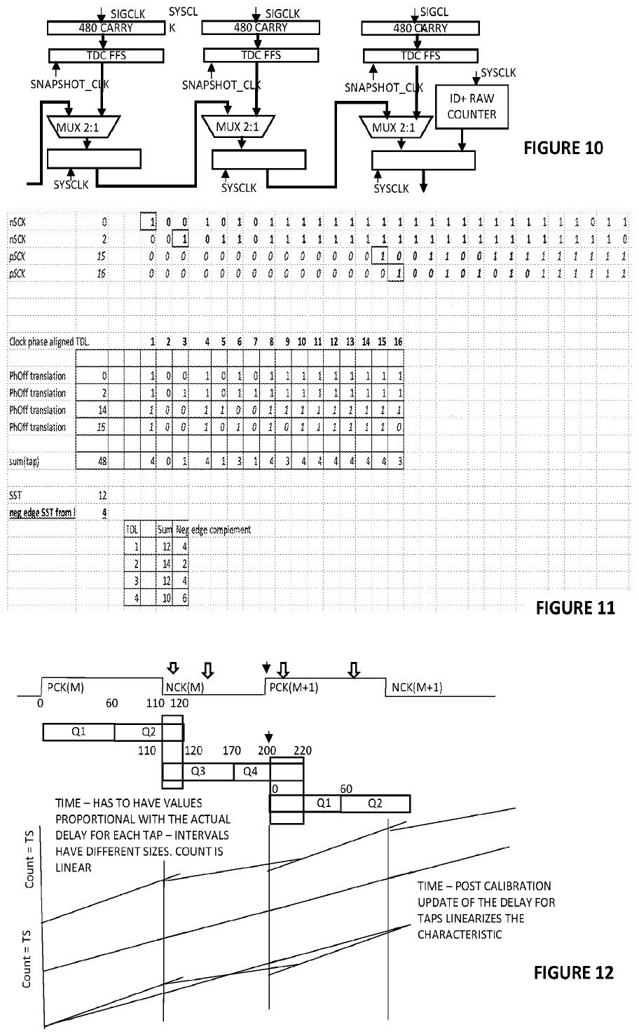

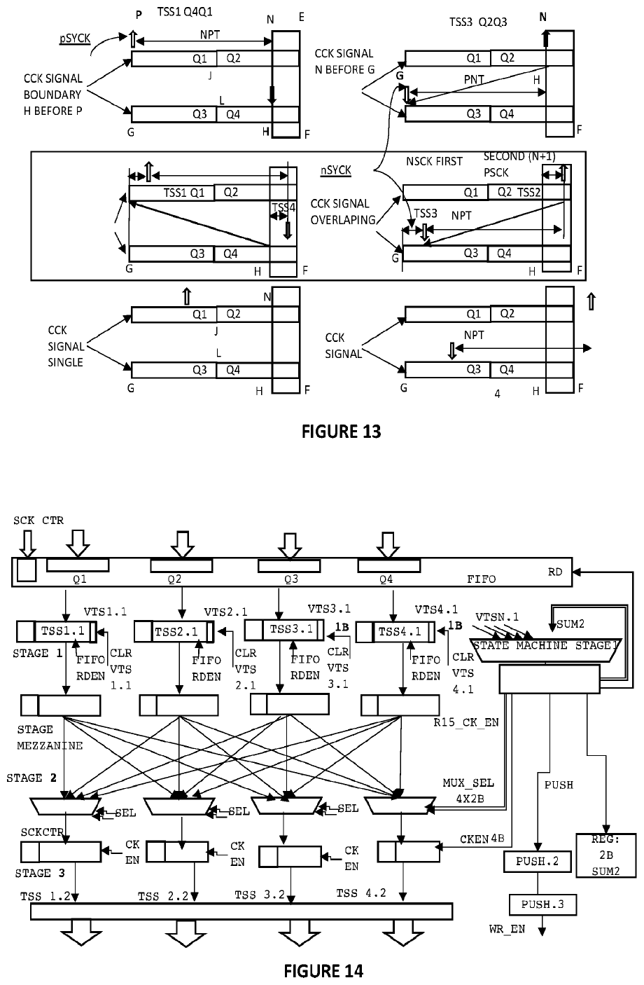

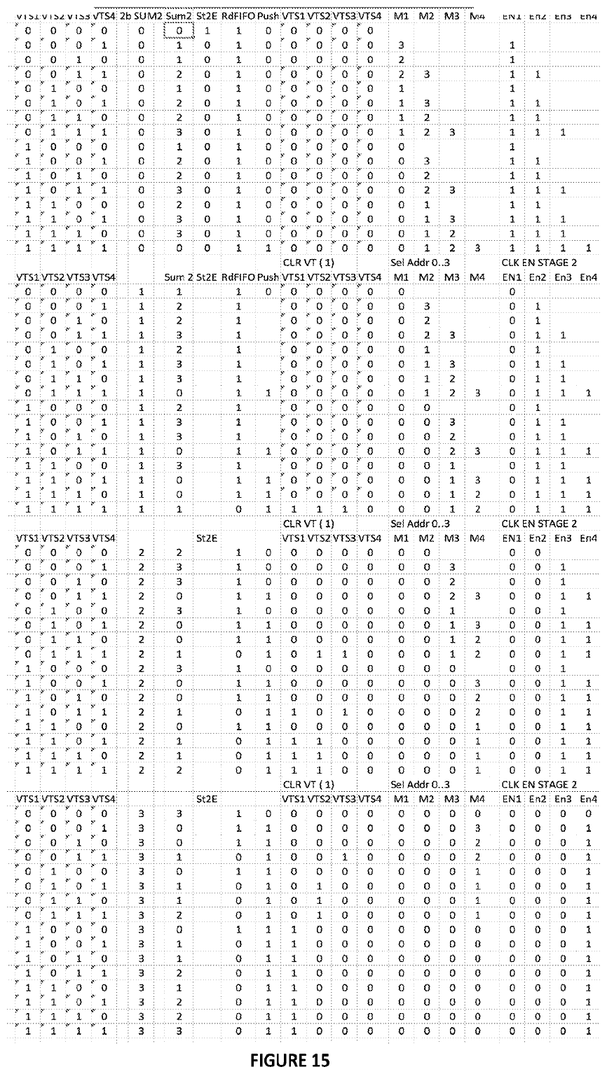

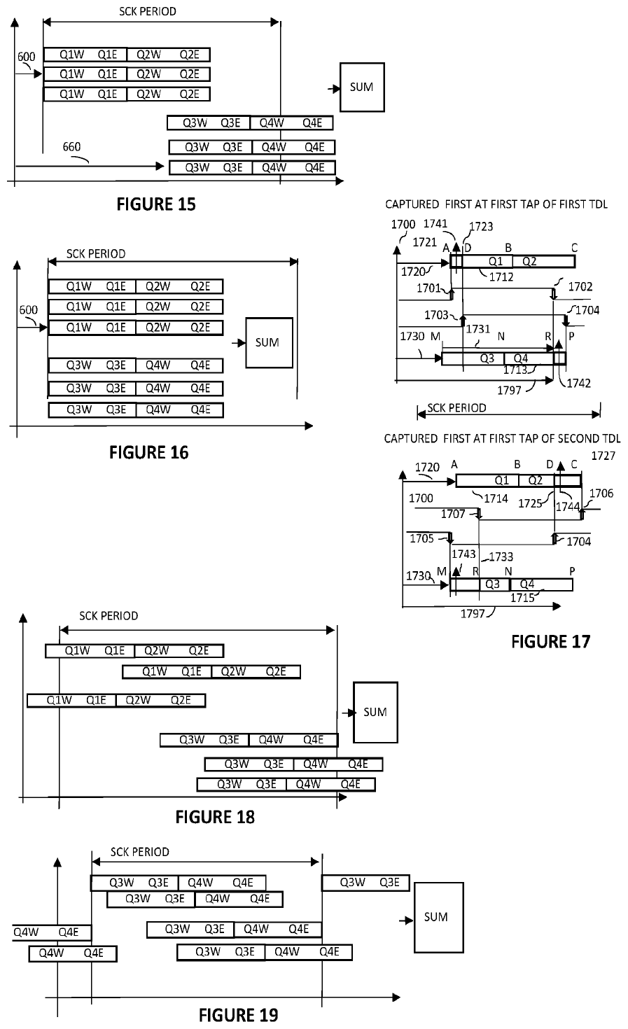

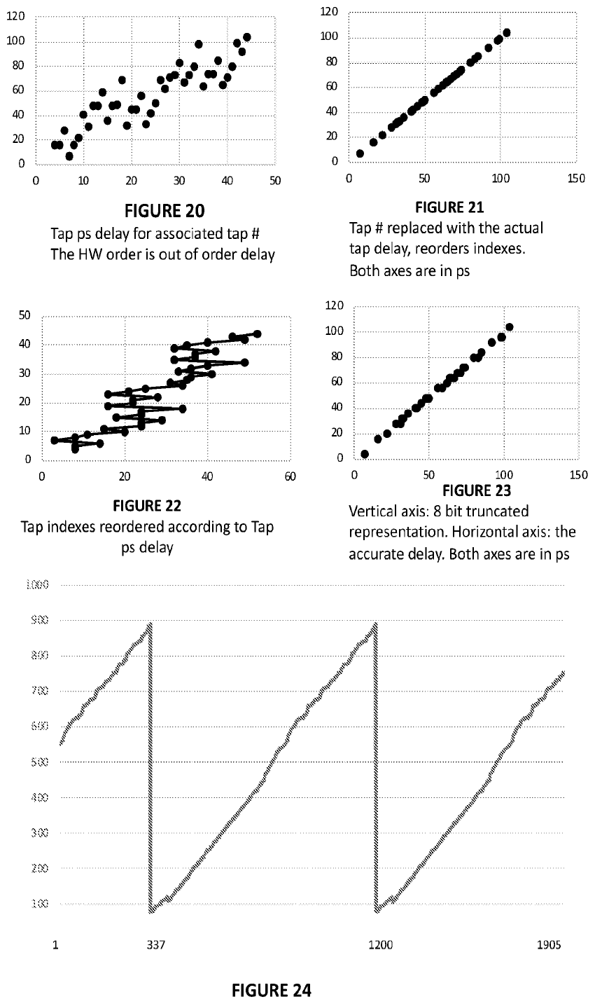

An embodiment disambiuates the inherent symmetry of TDLSecSE addition by splitting the TDLSec in slices (FIG. 8) and doing and comparing individual sum of slices near the ends of the TDLSec to determine the positive or negative nature of the transition.

One embodiment uses TDLs shorter than the latching clock period. Then multiple TDLs have to overlap each other to cover blind intervals, such that any event can be latched and timestamped. There are variables the system can control and combine: the propagation delay (PD) of TDL, the PhOff, and the latching clock parameters.

The signal routing on an FPGA has significant variations and but the FPGA has the flexibility of selecting from the diverse combinations of signal delays and the clock delays for a certain TDL to meet required performance.

An embodiment uses clock muxing buffers can be used to select the specific clock latching a specific TDL for an optimal, uniform overlapping of TDL for best coverage of events.

Another embodiment generates signals to identify the beginning and end of time overlapping between TDLs. Overlapping happens when the same input signal occurs and it is captured on a plurality of TDLs, when TDL are longer than the time interval between the clocks. A TDL can only latch signals which occur within its boundaries, covering its PD before the latching clock.

For example, in FIG. 4 signal 401 is captured on the pSCK(n+1) as reading 414 and also on the nSCK(n) as reading 416. The system will convert 416 to 416+(404−403), by adding the time difference between the nSCK and pSCK phases of the SCK. (in the example they are the alternative edges of the same clock)

To determine and calibrate the taps and the overlapping TDLSec sections the system uses the sweeping clock, or the vernier traveling wave test signal, where the transition edges of the signal advance a small fraction of pS for each system, latching clock.

For the sweeping clock test, the overlapping capture happen when there is a same polarity transition captured on different passed clocked DLs (nSCK and pSCK in the example 621, 631). An embodiment comprising one TDC provides individual signals at the output.

An embodiment comprising an ETDC, provides only the sum of TDLSecTS. ETDC does not provide at output access to individual TDLSecTS to determine time overlapping and double event capturing. We only know the tap superposition related numbers. Though considering the ETDC as a stand alone ETDL (with substantially more taps covering the same delay and the superimposed TDCs), and that the associated sum are monotonic because the terms in the sum are monotonic, accordingly an inverse is available, and the same TDC methods would apply to ETDC.
One embodiment is configuring offset for the pin to TDL to match measured delay.
TDLs have end to end delays longer than the difference between the adjacent clocks to be able to overlap and avoid blind spots. (FIG. 6) The rising edge of the first overlapping and falling edge of the last overlapping Valid signals determine the propagation delay over the TDL.

Due to propagation delay, variations on FPGA both the signal and the moment of latch will have different delays in between TDCs. For simplicity, will sum both delay and assign the result to the latching delay, PhOffx: 527=523+529, while assuming without reducing from generality that the signal to be measured reaches each TDC at the same time, wherein x is a TDC identification.

Retiming of all phases to one counted clock for pipe processing of addition Because the HW has a limited maximum clock, maxCK frequency and also the TDLD is smaller than the maxCK, the ETDC has to use parallel TDLs having interleaved latching times. One embodiment has several values for the signal delay to the TDL (FIG. 18), while having a common phase clock. Another embodiment has different phased clocks latching the parallel TDL while having similar propagation delay between the pin and the TDL input (FIG. 16). This parallel functional topology is equivalent with having a multiple of the SCK frequency performing multiple snapshots in one period of the clock. Such multiple of the clock frequency would exceed the maximum functional frequency of an FPGA or ASIC, but it is made possible through the parallel architecture providing multiple TDLs at different phase relations between PhOff and SCK, and splitting the TDL in TDL sectors. Therefore, the parallel structures may be necessary. The first option would have a common clock making digital processing easy, but the additional logic for the staggered delay (FIG. 19) adds noise. For the second option, the digital processing section of the ETDL has to have all snapshot data aligned to the system clock to perform the addition or averaging. This requires retiming logic between different clocks, but has less noise and jitter as the signal transport from the pin to the TDLs is done directly through the global clock lines.

An embodiment implements the ETDC with a look ahead pipe which provides maximum FPGA frequency. The processing pipe in FIG. 1,2 does not use feed-back loop resulting in much higher frequencies and better routing because there is no need for control signals to be distributed across all NumInst TDLs.

### Equivalent Representations of TDLs Coverage Relative to the SCK

The position of a signal transition captured on a TDL, as a snapshot (FIG. 6 601, AD) is the time interval between the event arrival at the TDL input and the SCK latching the TDLS. The event precedes the (696) SCK. An equivalent representation is to have A as the SCK and D as the event, considering the time flow is represented from right to left to maintain the temporal sequence.

The multiple TDLS can be accurately summed by compensating the relative offset, through shifting each TDLS by its measured PhOff Once aligned can sum the all the TDLSecS taps, generating a much more accurate determination of a transition.

### Identifying Transitions and their Polarity

In some embodiments, TDLs may be split into sectors, referred to as “TDLSecs” having a delay “TDLSecD” bigger than the minimum pulse duration, limited by the maximum frequency of the FPGA pin. TDLSec are further subdivided in slices TDLSecSla to determine the direction of transitions captured in TDLSecS. The taps of TDLSecSla are summed and compared. Also, the sum of each of the TDLSecSla is performed and compared with the other.

The sum of taps is left-right ambiguous (ex 1110 has the same sum=3 as 0111). But it is easy to slice in two sections and perform the sum of each. As example for sum=3 assuming the left slice is 11 the right 10 then 2>1 and a falling edge is identified.

An embodiment is identifying the position of a transition by comparing sum of 1 of adjacent sectors.

The minimum distance between transitions (pulse size) limits the number of transition in a TDLSec.
Ex: assume adjacent 6 tap sectors, with the sums and possible tap polarity:
3, 3, 4=111000, 000111, 111100 (3 transitions for 3 sectors)
3, 3, 2=000111, 111000, 000011 (3 transitions). But the combination 000111, 000111, 000011 is not possible because it violates the number of transitions (5 for 3 sectors).

One embodiment allows a maximum of one signal transition per Sector. This simplifies processing by eliminating ambiguities like 1110100000010111 or 0001011111101000. Another embodiment allows denser transition cases when the TDL size can be further reduced such that logic would address only one transition. For example having to smaller sectors as 11101000 and 00010111. The hardware implementation can scale the size of the Sectors to be smaller than the minimum pulse width to be measured. Additionally, the data redundance allows implementation of logic to identify double edges in a sector and set an error flag.

Another embodiment is merging same event readings with different clocks and in separate time domains. Without reducing from generality, we use convention that signals enter TDL from left and time flows from left to right in the representations.

Noisy transition happening at the boundary between sectors, are detected in both sectors. Same transition is identified by having the same edge in adjacent sectors, otherwise there must be three edges in two adjacent sectors, violating the minimum pulse width hypothesis. An embodiment adds the phase delay difference between the clock of two sectors to the latest (or sooner) TDS capture. Another embodiment subtracts the phase delay difference between the clocks of the two sectors to the earliest (or latest) TDS capture. These translate readings in two different clock, or time domain into the same time domain, of the reading between two clock sectors

Further embodiments may be configured to do the sum of all the taps in a TDLSec, sumTDLSec or TDLSecSE, and determine the direction of the edge of the transition, by comparing the sum of a plurality of bits, sumTDLSecSla, of a slice of TDLSec near the input of a TDLSec with a later sumTDLSecSla (relative to the TDL direction of signal propagation) of the TDLSec. If the left is bigger than the right, then it is a rising edge transition and the TDLSecTS=sum of bits in the sector, sumTDLSecS. Otherwise, it is a falling edge, and the TDLSecSE is the total taps minus the sumTDLSecS (it is complementing the sum).

An ETDC performs the sum of all Valid sumTDLSecTS and determines the number of Valids (Valid flag is active when adjacent compacts have different polarity).

The local Timestamp, relative to the TDLSec is corrected with PhOff of each TDLSec, and converted to a timestamp by further adding the relative phase offset to the latching edge of the local clock to the SCK. Double captured events in adjacent TDLSec are merged by translating one into the other time domain.

One embodiment detects one transition between adjacent compact sectors with different sums of their taps polarity (one has the maximum the other has the minimum sum) If adjacent sectors (or slices) sum is equal and both are different from 0 or the number of bits, there is an error in violation of the minimum pulse width hypothesis. An error flag is set.

If the sumTDLSecS is either 0 or maximum bit number then the sector is “compact”.
If adjacent sectors detect a Valid transition with the same edge polarity, then it is the same event. The reading of the two sectors must be unified by merging into one and invalidating the other TDLSecTS. An embodiment merges the adjacent TDLSecTS into the TDLSecTS which is earlier in time. Another embodiment merges timestamp into the sector which is later in time.

### 12. COMPACTOR

The Compactor ensures that only valid timestamps are passed to the next stage for transition. The compactor assembles only valid timestamps (TDLSecTS) on a register, and pushes to the next processing block only when it is fully loaded. The input data has four timestamps, one for each TDLSec of an embodiment. Any combination of Valid data among the TDLSecTS is possible. The output is filled from left to right in the order the timestamps were received, and in the order they were at the input (left to right or right to left). See FIG. 14.

### 13. PSEUDO DIFFERENTIAL LOGIC

Some embodiments may invert the event signal to half of the TDCs inputs. When the power rail drops negative edge will be delayed while the rising edge will be accelerated, according to the difference between the actual value of the signal and the transition point. As the ETDC sums the TDLSecTS from all TDLSec, the result should cancel the jitter resulting from power rail noise.

The power plains bounce generate jitter by changing the logic decision threshold. Now we provide another signal that is the inverse of the direct event signal. This is directed to an odd number TDC, while the direct signal goes to an even number TDC. Even TDC FF would latch later and Odd TDC FFs will latch sooner when the TDCs rails will go for lower voltage, as the Decision Threshold moved closer to the GND (assuming the even signal is high). The complementary changes compensate each other when added (ETDC). Moreover a weighting factor may be calculated for a perfect match (that is also dependent on the position of the transition on the delay line)—the factor is definitively for the next phase research, not a 2020 objective. Furthermore the inverted signal should be generated at the pin and routed as close as possible to the direct signal—to generate a coupling effect. Common mode noise would be compensated the same way indicated above.

1. A time to digital converter (TDC) comprising:
a tapped delay line (TDL) having two or more sectors, each sector of the two or more sectors having a dedicated or a shared latching clock, or two or more TDLs each having at least one sector, wherein each TDL of the two or more TDLs includes a dedicated latching clock for each sector; and
a snapshot register configured to latch each respective sector on its respective latching clock to generate respective thermometer readings (TDLSecSs).

2. The TDC of claim 1 further comprising at least one encoder configured to generate a numerical representation (TDLSecSE) of each of the thermometer readings, wherein each TDLSecSE is generated by encoding a location of a transition in a TDLSecS or between adjacent TDLSecSs.

3. The TDC of claim 2 further comprising one or more adders, wherein the one or more adders are configured to generate a timestamp (TDLSecTS) for each respective TDLSecSE by adding a delay (PhOff) to each respective TDLSecSE, wherein the delay is relative to a common reference.

4. The TDC of claim 3 further comprising a processor, wherein the processor is configured to determine a sum or an average of TDLSecTSs generated by an event signal.

5. The TDC of claim 2 where encoding comprises:
a. calculating a sum of all bits of the TDLSecSs; and
b. if the sum is different from a compact sum which is either null or equal with a total number of bits of TDLSecS, and
i. the sum of a first plurality of bits near the signal entry to the TDLSecS is bigger than the sum of a second plurality of bits at the opposite end of the TDLSecS, then TDLSecSE referenced from the end point of signal entry to TDLSecS is valid and is equal with the sum, and the transition is a rising edge, or
ii. the sum of a first plurality of bits near the end point of signal entry to the TDLSecS is smaller than the sum of a second plurality of bits at the opposite end of the TDLSecS then TDLSecSE, referenced from the signal entry end point of TDLSecS is valid and is equal with the difference between the number of bits in the TDLSecS and the sum, and the transition is a falling edge; or
c. if the sum of TDLSecS is compact and not null and the sum of an adjacent TDLSecS connected at the output of the TDLSecS is compact and null then the TDLSecSE referenced from the end point of signal entry of TDLSecS is the total number of bits of TDLSecS, and the transition is valid and is positive,
d. if the sum of TDLSecS is compact and null and the sum of an adjacent TDLSecS connected at the output of the TDLSecS is compact and not null then the TDLSecSE referenced from the end point of signal entry of TDLSecS is the total number of bits of TDLSecS and the transition is negative, or
e. if the sum of TDLSecS is compact and the sum of an adjacent TDLSecS connected at the output of the TDLSecS is also compact and both sums are equal TDLSecSE is not valid.

6. The TDC of claim 3 wherein a maximum number of timestamps generated by the TDC at an output is up to a maximum number of sectors on TDLs with different clocks and the maximum number of sectors on TDLs with different clocks is further divided by a number of latching clock periods in between each generated timestamp from each TDLSecS.

7. The TDC of claim 1 wherein a minimum time interval between two timestamps is equal or greater than a TDLSec time interval.

8. The TDC of claim 1 further comprising:
a) A first snapshot subsystem comprising:
i. a first TDL connected to an event signal and latched into a first snapshot register by a first clock,
ii. a second clock with a known, deterministic relation to the first clock, and
iii. the second TDL connected to the event signal and latched into a second snapshot register by the second clock; and
b) A second snapshot subsystem comprising:
iv. a third TDL connected to the event signal and latched into a third snapshot register by the first clock, and
v. a fourth TDL connected to the event signal and latched into a fourth snapshot register by the second clock; and
c) A logic block generating timestamps from data collected in the four snapshot registers from both snapshot subsystems.

9. The TDC of claim 1 further comprising a logic block further comprises:
a processing unit configured to perform either:
an average of a tap delay of a signal transition in a time overlapping section at one end of the first snapshot register with a tap delay of a signal transition in the time overlapping section at the other end of the second snapshot register, or
a selection among the tap delay of a signal transition signal in the time overlapping section at one end of the first snapshot register and the tap delay of a signal transition signal in the time overlapping section at the other end of the second snapshot register.

10. The TDC of claim 1, wherein the TDC includes the two or more TDLs including a first TDL and a second TDL, wherein a signal transition is captured on the first TDL, on the second TDL, or an overlapping section of the first and second TDL.

11. The TDC of claim 1 wherein each TDL has a propagation delay shorter than a period of its respective latching clock.

12. The TDC of claim 11, wherein any signal transition is captured by a plurality of the TDLs.

13. The TDC of claim 1, wherein the TDC is configured to:
measure FPGA hardware and select TDL taps and associated routing to latching registers for a preselected FPGA CARRY chain, or
select, from a plurality of FPGA CARRY chains, a subset of the plurality of FPGA CARRY chains having TDL taps distributions,
wherein the delay between consecutive TDL taps of the subset of FPGA CARRY chains or preselected FPGA CARRY chain is similar or equal.

14. The TDC of claim 1 further comprising a raw counter of a first latching clock or a raw counter of a second latching clock or both or an additional software counter for either or both the raw counters wherein the raw counter wraps around and provides and provides a dynamic range equal with a maximum count number.

15. The TDC of claim 1 wherein a shortest detectable signal pulse is a propagation time of a signal through a TDLSec.

16. The TDC of claim 1, wherein the TDC is configured to measure a respective delay of each TDL tap through a calibration process.

17. The TDC of claim 1, wherein the TDC is further configured to convert a TDL tap number of a transition into a propagation delay from an input of a sector to the TDL tap.

18. The TDC of claim 1, wherein the TDC is further configured to measure a relative propagation delay offset (PhOff) between a common signal reference point and the first TDL tap of each TDL.

19. The TDC of claim 1 further configured to disambiguate a signal transition, wherein disambiguating the same signal event in a time overlapping section of two adjacent TDLSec, includes:
a. determining the start and ending tap number or time of the overlapping section of two time adjacent TDLSec by identifying a range where same polarity transition is detected on both TDLSecs,
b. converting the transition (TDLSecSE) from one of the TDLSec to the other TDLSec by adding a time constant or subtracting another time constant, and
c. adding or averaging the two TDLSecSE at the same TDLSec.

20. The TDC of claim 19 wherein the time constant is added to the earlier timestamp captured by the first TDLSecS for conversion to the second TDLSecS, or
the time constant subtracted from the later timestamp captured by the second TDLSecS for conversion to the first TDLSecS is a difference of the PhOff of the first TDLSecS and the PhOff of the second TDLSecS.

21. The TDC of claim 1, wherein the TDC is further configured to retime the TDLSecS or TDLSecSE captured by one of the TDL with a second clock, to become contemporaneous to a time domain of a first clock.

22. Claim 1 further comprising the step of converting the timing of transition events captured at a TDLSec to a timestamp relative to the signal input pin of the device:
a. Determining a PhOffSec time delay between the device pin and the first tap of the TDLSec input
b. Determining a phase offset, PhOffSCK between the latching clock of TDLSecS and the reference clock incrementing the SCKCTR,
c. Adding the PhOffSCK, and the PhOffSecto the TDLSecSE of the sector.

23. The TDC of claim 1, wherein the TDC is further configured to perform a calibration and measure of a sector through a sweeping wave comprising by:
a. selecting a Phase Progression constant, representing the precision of the measurement, and
i. generating a signal with a period determined by the period of the first clock modified by the Phase Progression; or
b. generating a signal with a period close to the first clock, and
i. determining the Phase Progression by counting a first number of periods of the first clock between transitions of same polarity of the same tap of the sector, and dividing the period of the first clock by the first number of periods; and
c. determining the delay of a tap by counting a second number of periods of the first clock between a transition of the first tap of and a transition of the second tap, and
d. multiplying the second number of periods with the phase progression.

24. The TDC of claim 23 where the calibration is performed separately for the positive edge or for the negative edge of the event signal, or for both.

25. The TDC of claim 1 further comprising a LUT to linearize, or convert tap numbers to a time delay of the tap number for the positive edge or for the negative edge of the event signal, or for both.

26. The TDC of claim 1 further implementing a pseudo differential logic to mitigate noise, wherein the logic inverts the signal polarity for half of the TDL inputs of an ETDC and restores the original polarity by inverting the TDLSecS.
